(19) United States
(12) Patent Application Publication
(10) Pub. No.: US 2026/0177908 A1
(43) Pub. Date: Jun. 25, 2026

(54) MOLDING APPARATUS, METHOD OF MOLDING, AND METHOD OF PLANARIZATION

(71) Applicant: CANON KABUSHIKI KAISHA, Tokyo (JP)

(72) Inventors: Masayuki Tanabe, Tochigi (JP); Keiko Chiba, Tochigi (JP); Keiji Yamashita, Tochigi (JP); Keita Sakai, Tochigi (JP); Toshiki Ito, Kanagawa (JP); Naoki Kiyohara, Tokyo (JP)

(21) Appl. No.: 19/540,401

(22) Filed: Feb. 13, 2026

Related U.S. Application Data
(63) Continuation of application No. 17/707,728, filed on Mar. 29, 2022.

(30) Foreign Application Priority Data
Mar. 31, 2021 (JP) 2021-059050

(51) Int. Cl. G03F 7/00; B29C 59/00; B29C 59/02

(52) U.S. Cl. CPC G03F 7/0002; B29C 59/002; B29C 59/022

(57) ABSTRACT

A molding apparatus includes a mechanism configured to apply a curable composition onto a substrate with irregularities, a pressing and releasing mechanism that presses or releases a mold (super straight) having a flat surface against the curable composition on the substrate, and a curing mechanism configured to cure the curable composition by light radiation, a first supply unit configured to supply a first gas to the curable-composition application mechanism, and a second supply unit configured to supply a second gas different from the first gas to the pressing and releasing mechanism.

### CROSS-REFERENCE TO RELATED APPLICATIONS

This application is a continuation of U.S. patent application Ser. No. 17/707,728, filed on Mar. 29, 2022, which claims priority from Japanese Patent Application No. 2021-059050, filed Mar. 31, 2021, which are hereby incorporated by reference herein in their entireties.

### BACKGROUND

### Field of the Disclosure

The present disclosure relates to a molding apparatus and a method of molding, and in particular, relates to an apparatus and a method for planarizing the surface of a substrate.

### Description of the Related Art

A photolithography process for producing a semiconductor device requires to highly mold the surface of a substrate, and in particular, to form (planarize) a flat surface with no irregularities. For example, with an extreme-ultraviolet (EUV) exposure technique, which is a photolithography technique that has received attention in recent years, the depth of focus at which a projected image is formed decreases with miniaturization. For this reason, the surface irregularities of the substrate to which a photoresist is applied needs to be below 4 nm.

With another photolithography technique, a nanoimprint lithography (NIL) technique, flatness similar to that of the EUV is required to improve the filling performance and the accuracy of the line width.

In the semiconductor industry, the most common planarization technique is chemical mechanical polishing (CMP). The CMP, which is developed to planarize hard materials, such as metal and dielectric materials, has some drawbacks. Application of the CMP to soft materials, such as organic compounds, requires expensive strict process control, which is difficult for practical use. For a recessed portion of several μm or more, the CMP also has the problem of dents due to polishing.

Another planarization technique uses an ink jet technique to eject (dispense) droplets of a polymerizable imprint material (a curable composition) between the surface of a substrate and a template, as disclosed in Japanese Patent No. 6495283. The pattern of the droplets applied onto the substrate is changed according to the irregularities of the substrate surface and brings the applied curable composition and the template into contact with each other. Thereafter, the curable composition is solidified in a state in which it is in contact with the template.

Next, the solidified curable composition and the foundation substrate are released from the template to form a planarized substrate. The droplet pattern applied to the substrate surface by the ink jet technique is adjusted so as to complement the influence of, for example, the variation of the density of the curable composition that fills the irregularity pattern formed on the surface.

However, the method disclosed in Japanese Patent No. 6495283 may cause the gas in the environmental atmosphere to be taken into the curable composition at the contact with the template. This can cause bubbles in the formed film, resulting in that the curable composition is cured with a non-filling defect.

### SUMMARY

The present disclosure provides a planarizing apparatus and a method of planarization capable of reducing or eliminating a non-filling defect as well as advanced planarization of an uneven substrate.

A molding apparatus according to an aspect of the present disclosure includes an application unit configured to apply a curable composition on a substrate, a curing unit configured to cure the curable composition, a first supply unit configured to supply a first gas that decreases viscosity of the curable composition to the curable composition, and a deaeration unit configured to release the first gas supplied by the first supply unit from the curable composition.

The present disclosure provides a planarizing apparatus in which both of filling performance and flatness are satisfied.

Further features of the present disclosure will become apparent from the following description of exemplary embodiments with reference to the attached drawings.

### BRIEF DESCRIPTION OF THE DRAWINGS

FIG. 1 is a diagram illustrating a planarizing apparatus according to a first embodiment.

FIG. 2 is a table listing examples of condensable gases that can be used as a first gas in the embodiments.

FIG. 3 is a flowchart for a method of planarization according to the first embodiment.

FIG. 4 is a graph showing the relationship between the concentration of the condensable gas and the spread area of the droplets of a curable composition.

FIG. 5 is a diagram illustrating a planarizing apparatus according to a second embodiment.

FIG. 6 is a flowchart for a method of planarization according to the second embodiment.

FIG. 7 is a diagram illustrating a planarizing apparatus according to a third embodiment.

FIG. 8 is a flowchart for a method of planarization according to the third embodiment.

FIG. 9 is a diagram illustrating a planarizing apparatus according to fourth and fifth embodiments.

FIG. 10 is a flowchart for a method of planarization according to the fourth and fifth embodiments.

FIG. 11 is a diagram illustrating a planarizing apparatus according to a sixth embodiment.

FIG. 12 is a flowchart for a method of planarization according to the sixth embodiment.

FIG. 13 is a diagram illustrating a planarizing apparatus according to a seventh embodiment.

FIG. 14 is a flowchart for a method of planarization according to the seventh embodiment.

### DESCRIPTION OF THE EMBODIMENTS

Embodiments of the present disclosure will be described in detail hereinbelow with reference to the drawings.

### First Embodiment

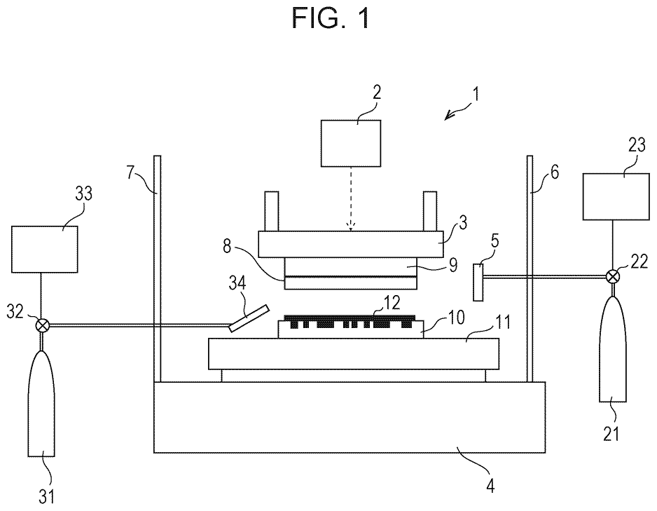

FIG. 1 is a diagram illustrating a planarizing apparatus according to a first embodiment. The planarizing apparatus is used to produce devices, such as semiconductor devices, and molds a curable composition (typically, an uncured curable composition) on a substrate, which is a workpiece, with a mold having a flat surface (a super straight) to mold a flat surface pattern (typically, a curable composition pattern) on the substrate.

Here, the planarizing apparatus employs a photo-curing method. In the following diagrams, the Z-axis is taken parallel to the optical axis of an illumination system that applies ultraviolet light to the curable composition on the substrate, and the X-axis and the Y-axis intersecting at right angles are taken in a plane perpendicular to the Z-axis. The planarizing apparatus 1 includes an illumination system 2, a mold holding unit 3, a substrate stage 4, an application unit 5, a first supply mechanism 6, and a second supply mechanism 7.

The illumination system 2 is an illumination unit that applies ultraviolet light to a super straight 8 that allows ultraviolet light to pass therethrough at an imprinting process. The illumination system 2 includes a light source and an optical element for adjusting the ultraviolet light emitted from the light source to light suitable for imprinting (not shown). The super straight 8 is a mold having a very flat surface facing a substrate 10 with irregularities. The super straight 8 is made of a material that allows ultraviolet light to pass through, such as quartz.

The mold holding unit 3 is a holding unit that attracts the super straight 8 using a vacuum attracting force or an electrostatic force. The mold holding unit 3 includes a super straight chuck 9 and a mold driving mechanism (not shown) that drives the mold holding unit 3 in the direction of Z-axis to press the super straight 8 against the ultraviolet curable composition applied on the substrate 10. Mold pressing and releasing operations of the planarizing apparatus 1 may be performed by moving the super straight 8 in the Z direction or may be performed by moving the substrate stage 4 (the substrate 10) in the Z direction or both of the super straight 8 and the substrate stage 4.

The substrate stage 4 is a holding unit including a substrate chuck 11 that holds the substrate 10 by vacuum attraction, for example, and that is movable in an X-Y plane. The substrate 10 is a workpiece made of, for example, monocrystal silicon, on which a curable composition 12 to be molded by the super straight 8 is applied.

The application unit 5 applies the curable composition 12 (uncured curable composition) onto the substrate 10. The curable composition 12 is a photocurable composition having the property of being cured by receiving ultraviolet light and is selected as appropriate in, for example, a semiconductor device manufacturing process.

The application unit 5 may be any application unit that can apply liquid curable composition onto the substrate 10 but may be a unit that uses an ink jet technique for ejecting droplets of a curable composition from an ejecting unit.

The first supply mechanism 6 is a supply unit that supplies a first gas for reducing the viscosity of the curable composition 12. The first supply mechanism 6 communicates with the application unit 5, which allows the supplied gas to be mixed with the curable composition 12 in the application unit 5. The first gas supplied from the first supply mechanism 6 dissolves in the curable composition 12 to reduce the viscosity of the curable composition 12, thereby improving the filling performance. The first supply mechanism 6 includes a condensable-gas supply unit 21 that supplies the first gas, which is a condensable gas having the property of being condensed into liquid when pressure is applied (when the pressure is increased).

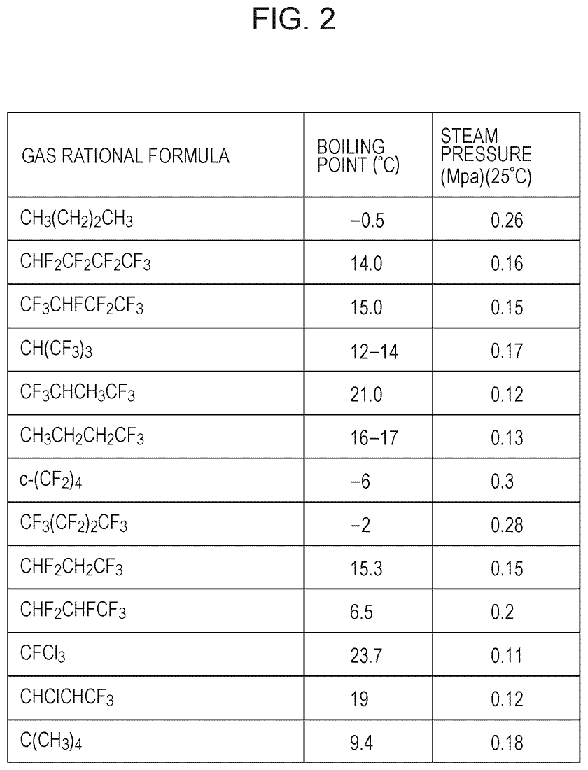

The condensable gas is a gas whose boiling point under atmospheric pressure is from −10° C. to 25° C. or a gas whose vapor pressure at 25° C. is from 0.1 to 0.4 MPa. An employable example of the condensable gas is hydrofluoroether (HFE) typified by HFE-245mc (CF₃CF₂OCH₃). An alternative example of the condensable gas is hydrofluorocarbon (HFC) typified by HFC-245fa (1, 1, 1, 3, 3-pentafluoropropane, CHF₂CH₂CF₃). Typical condensable gases that can be used as the first gas in the present disclosure are shown in FIG. 2. The first supply mechanism 6 further includes a valve 22 and a gas-supply control unit 23 that controls the amount of gas supplied.

The application unit 5 may be of a cartridge type, in which the condensable gas may be mixed with the curable composition 12 in advance. The use of the condensable-gas supply unit 21 allows correcting a change in the amount of the mixture due to a temperature change.

Mixing the condensable gas in the application unit 5 allows decreasing the viscosity of the high-viscosity curable composition 12, which is difficult to apply by dispensing or which needs an extremely high voltage. This increases options of the curable composition, allowing for selecting a curable composition having high performance required for curable compositions, such as the percentage of contraction and resistance to dry etching.

The second supply mechanism 7 is a supply unit that supplies a second gas toward a pressing position at which the super straight 8 and the curable composition 12 on the substrate 10 are pressed to each other during the period after the curable composition 12 is applied to the substrate 10 until the pressing. The second supply mechanism 7 may include a permeable-gas supply unit 31 that supplies the second gas, which is a permeable gas having the property of melting or diffusing, to at least one of the super straight 8 and the substrate 10. Employable examples of the permeable gas include helium and hydrogen gases. However, if flammable hydrogen is used as the permeable gas, the imprinting apparatus 1 needs to house an explosion-proof system for protection against fire. The second gas may have low solubility in the curable composition or a low volume ratio even if it is dissolved so as to prevent affecting the contraction of the curable composition pattern when the second gas is released from the cured curable composition pattern. The second gas supplied from the second supply mechanism 6 may be air, nitrogen, or another inert gas. The second supply mechanism 7 further includes a valve 32, a gas-supply control unit 33 that controls the amount of gas supplied, and a gas supply nozzle 34. The use of the second supply mechanism 7 allows the first gas dissolved in the curable composition 12 to be released from the curable composition 12. To release the first gas from the curable composition 12, a mechanism for decompressing the space between the curable composition on the substrate and the super straight may be provided. A mechanism for heating the curable composition on the substrate may be provided.

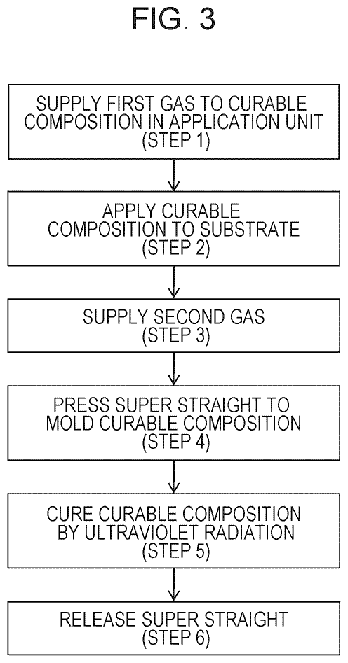

Next, a planarization process performed by the planarizing apparatus 1 will be described. FIG. 3 is a flowchart for the method of planarization according to this embodiment.

First, the first gas is supplied from the first supply mechanism 6 to the curable composition 12 in the application unit 5 of FIG. 1 (Step 1). The first gas dissolves in the curable composition 12 in the application unit 5 to decrease the viscosity.

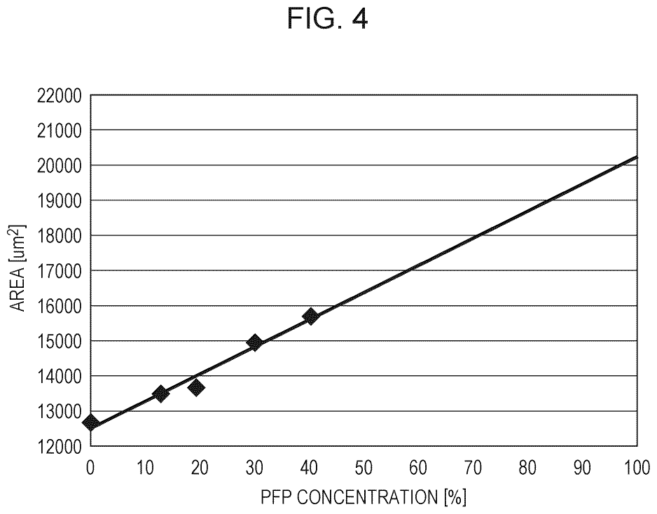

Next, the substrate 10 with irregularities is placed and fixed on the substrate stage 4 by a substrate conveying apparatus (not shown) and thereafter, the substrate stage 4 is moved to an application position of the curable-composition application unit 5. Thereafter, the curable composition 12 is applied from the curable-composition application unit 5 onto the substrate 10 (Step 2). The amount of the curable composition 12 to be ejected from the curable-composition application unit 5 to individual portions of the substrate 10 is adjusted according to the layout of the irregularities of the substrate 10. The curable composition 12 ejected to the substrate 10 spreads over the substrate 10. The viscosity of the curable composition 12 is decreased by the first gas dissolved in the curable-composition application unit 5, which enhances the spread over the substrate 10, preventing non-filling defects. FIG. 4 is a graph showing the relationship between the concentration of the condensable gas and the spread area of the droplets of the curable composition 12. Thus, the condensable gas enhances the spread of the droplets.

Next, the substrate stage 4 is moved to a position under the mold holding unit 3 by a substrate conveying apparatus (not shown). Thereafter, the second gas is supplied from the second supply mechanism 7 to a space between the curable composition 12 on the substrate 10 and the super straight 8 (Step 3). The supply of the second gas causes the first gas dissolved in the curable composition 12 to be released from the curable composition 12. The first gas has high solubility in the curable composition 12. For this reason, if the curable composition 12 in which the first gas is dissolved is cured, the curable composition pattern is contracted to decrease in flatness because the first gas is released from the cured curable composition pattern after the super straight 8 is separated (Step 6, described later). For this reason, the first gas may be released from the curable composition 12 while a space to which the first gas is released remains before the curable composition 12 is cured. The release of the first gas may be accelerated by decreasing the pressure in the space between the curable composition 12 on the substrate 10 and the super straight 8. The release of the first gas may be accelerated by heating the curable composition 12 on the substrate 10.

Next, the curable composition 12 is molded by pressing the super straight 8 to the curable composition 12 on the substrate 10 with a super-straight driving mechanism (not shown) (Step 4). In this state, the illumination system 2 applies ultraviolet light from the top (back) of the super straight 8 to cure the curable composition 12 with the ultraviolet light that has passed through the super straight 8 (Step 5). After the curable composition 12 is cured, the super-straight driving mechanism is activated again to release the super straight 8 from the substrate 10 (Step 6). At that time, the first gas is not released from the curable composition 12, so that the curable composition pattern is not contracted by the released first gas, keeping the flatness.

Thus, this embodiment provides a planarizing apparatus and a method of planarization that are advantageous in satisfying both of filling performance and flatness.

### Second Embodiment

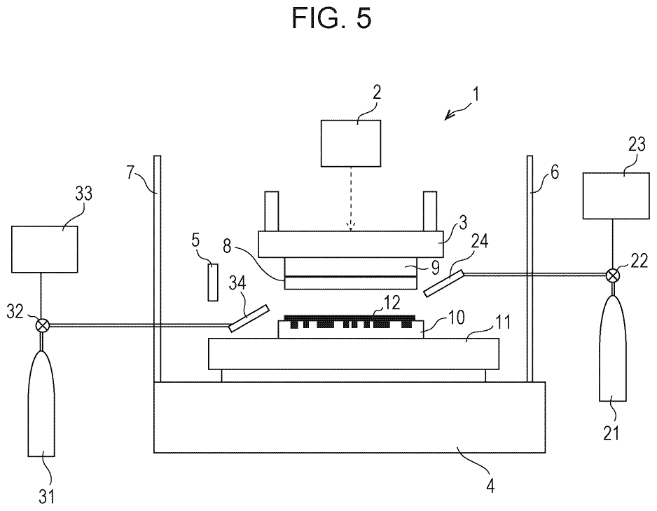

A planarizing apparatus according to a second embodiment will be described with reference to FIG. 5. FIG. 5 is a diagram illustrating the planarizing apparatus of the second embodiment. The planarizing apparatus is used to produce devices, such as semiconductor devices, and molds a curable composition (typically, an uncured curable composition) on a substrate, which is a workpiece, with a mold having a flat surface (a super straight) to mold a flat surface pattern (typically, a curable substance pattern) on the substrate. Here, the planarizing apparatus employs a photo-curing method. In the following diagrams, the Z-axis is taken parallel to the optical axis of an illumination system that applies ultraviolet light to the curable composition on the substrate, and the X-axis and the Y-axis intersecting at right angles are taken in a plane perpendicular to the Z-axis. The planarizing apparatus 1 includes an illumination system 2, a mold holding unit 3, a substrate stage 4, an application unit 5, a first supply mechanism 6, and a second supply mechanism 7.

The illumination system 2 is an illumination unit that applies ultraviolet light to a super straight 8 at an imprinting process. The illumination system 2 includes a light source and an optical element for adjusting the ultraviolet light emitted from the light source to light suitable for imprinting (not shown). The super straight 8 is a mold having a very flat surface facing a substrate 10 with irregularities. The super straight 8 is made of a material that allows ultraviolet light to pass through, such as quartz.

The mold holding unit 3 is a holding unit that attracts the super straight 8 using a vacuum attracting force or an electrostatic force. The mold holding unit 3 includes a super straight chuck 9 and a mold driving mechanism (not shown) that drives the mold holding unit 3 in the direction of Z-axis to press the super straight 8 against the ultraviolet curable composition applied on the substrate 10. Mold pressing and releasing operations of the planarizing apparatus 1 may be performed by moving the super straight 8 in the Z direction or may be performed by moving the substrate stage 4 (the substrate 10) in the Z direction or both of the super straight 8 and the substrate stage 4.

The substrate stage 4 is a holding unit including a substrate chuck 11 that holds the substrate 10 by vacuum attraction, for example, and that is movable in an X-Y plane. The substrate 10 is a workpiece made of, for example, monocrystal silicon, on which a curable composition 12 to be molded by the super straight 8 is applied.

The application unit 5 applies the curable composition 12 (uncured curable composition) onto the substrate 10. The curable composition 12 is a photocurable composition having the property of being cured by receiving ultraviolet light and is selected as appropriate in, for example, a semiconductor device manufacturing process.

The first supply mechanism 6 is a supply unit that supplies a first gas for reducing the viscosity of the curable composition 12 to aerate the curable composition 12. The first supply mechanism 6 supplies the first gas toward the substrate 10 in an application process in which the curable composition 12 is applied onto the substrate 10. The first gas supplied from the first supply mechanism 6 dissolves in the curable composition 12 to reduce the viscosity of the curable composition 12, thereby improving the filling performance. The first supply mechanism 6 includes a condensable-gas supply unit 21 that supplies the first gas, which is a condensable gas having the property of being condensed into liquid when pressure is applied (when the pressure is increased).

Usable examples of the first gas include HFE and HFC, described above. The first supply mechanism 6 further includes a valve 22, a gas-supply control unit 23 that controls the amount of gas supplied, and a gas supply nozzle 24.

The second supply mechanism 7 is a supply unit that supplies a second gas toward a pressing position at which the super straight 8 and the curable composition 12 on the substrate 10 are pressed to each other during the period after the curable composition 12 is applied to the substrate 10 until the pressing. The second supply mechanism 7 may include a permeable-gas supply unit 31 that supplies the second gas, which is a permeable gas having the property of melting or diffusing, to at least one of the super straight 8, the curable composition 12, and the substrate 10. Employable examples of the permeable gas include helium and hydrogen gases. However, if flammable hydrogen is used as the permeable gas, the imprinting apparatus 1 needs to house an explosion-proof system for protection against fire. The second gas supplied from the second supply mechanism 6 may be air, nitrogen, or another inert gas. The second supply mechanism 7 further includes a valve 32, a gas-supply control unit 33 that controls the amount of gas supplied, and a gas supply nozzle 34. The use of the second supply mechanism 7 allows the first gas dissolved in the curable composition 12 to be released from the curable composition 12. To release the first gas from the curable composition 12, a decompressing mechanism for decompressing the space between the curable composition on the substrate and the super straight may be provided. A heating mechanism for heating the curable composition on the substrate may be provided.

### Method of Planarization

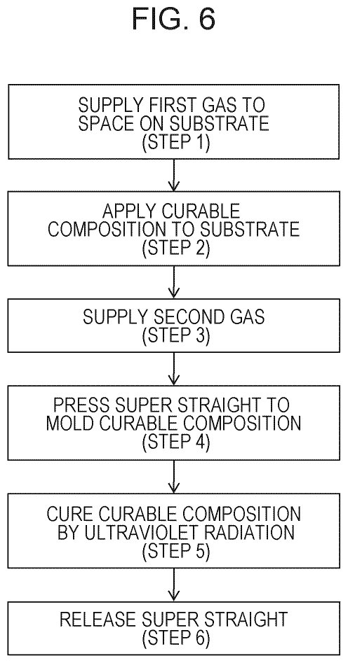

Next, a planarization process performed by the planarizing apparatus 1 will be described. FIG. 6 is a flowchart for the method of planarization according to this embodiment.

First, the substrate 10 with irregularities is placed and fixed on the substrate stage 4 by a substrate conveying apparatus (not shown), and thereafter the substrate stage 4 is moved to an application position of the curable-composition application unit 5. Thereafter, the first gas is supplied from the first supply mechanism 6 into the space between the substrate 10 and the super straight 8 (Step 1).

Next, the curable composition 12 is applied from the curable-composition application unit 5 onto the substrate 10 (Step 2).

The amount of the curable composition 12 to be ejected from the curable-composition application unit 5 to individual portions of the substrate 10 is adjusted according to the layout of the irregularities of the substrate 10. The viscosity of the curable composition 12 is decreased by the first gas dissolved in the curable-composition application unit 5. The decrease in the viscosity enhances the spread of the curable composition 12 over the substrate 10, preventing non-filling defects.

Next, the substrate stage 4 is moved to a position under the mold holding unit 3 by a substrate conveying apparatus (not shown). Thereafter, the second gas is supplied from the second supply mechanism 7 to a space between the curable composition 12 on the substrate 10 and the super straight 8. The supply of the second gas causes the first gas dissolved in the curable composition 12 to be released from the curable composition 12. The first gas has high solubility in the curable composition 12. For this reason, if the curable composition 12 in which the first gas is dissolved is cured, the curable composition pattern is contracted to decrease in flatness because the first gas is released from the cured curable composition pattern after the super straight 8 is separated (Step 6, described later). For this reason, the first gas may be released from the curable composition 12 while a space to which the first gas is released remains before the curable composition 12 is cured. The release of the first gas may be accelerated by decreasing the pressure in the space between the curable composition 12 on the substrate 10 and the super straight 8. The release of the first gas may be accelerated by heating the curable composition 12 on the substrate 10.

Next, the curable composition 12 is molded by pressing the super straight 8 to the curable composition 12 on the substrate 10 with a super-straight driving mechanism (not shown) (Step 4). In this state, the illumination system 2 applies ultraviolet light from the top (back) of the super straight 8 to cure the curable composition 12 with the ultraviolet light that has passed through the super straight 8 (Step 5). After the curable composition 12 is cured, the super-straight driving mechanism is activated again to release the super straight 8 from the substrate 10 (Step 6). At that time, the first gas is not released from the curable composition 12, so that the curable composition pattern is not contracted by the released first gas, allowing keeping the flatness.

Thus, this embodiment provides a planarizing apparatus and a method of planarization that are advantageous in satisfying both of filling performance and flatness.

### Third Embodiment

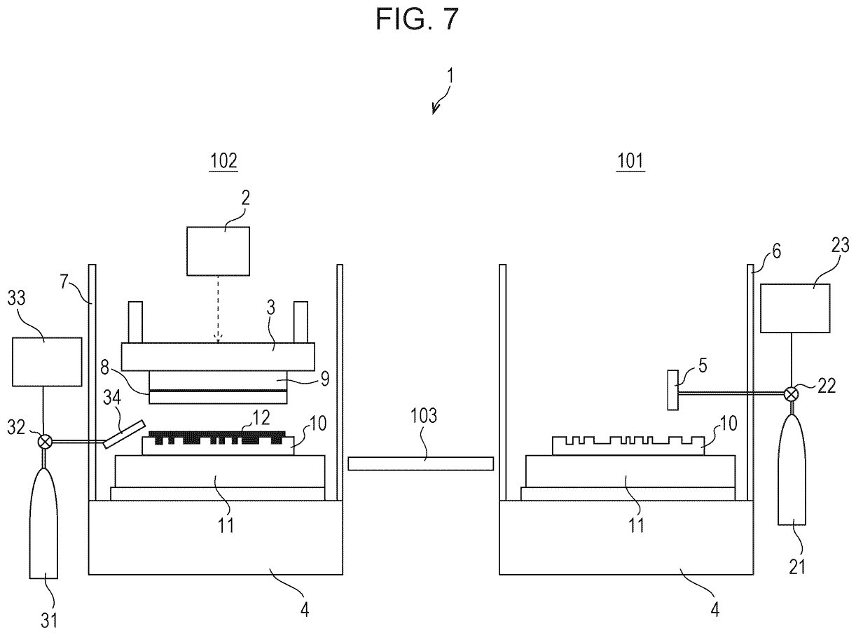

A planarizing apparatus according to a third embodiment will be described with reference to FIG. 7. FIG. 7 is a diagram illustrating the planarizing apparatus of the third embodiment. The planarizing apparatus is used to produce devices, such as semiconductor devices, and molds a curable composition (typically, an uncured curable composition) on a substrate, which is a workpiece, with a mold having a flat surface (a super straight) to mold a flat surface pattern (typically, a curable substance pattern) on the substrate. Here, the planarizing apparatus employs a photo-curing method. In the following diagrams, the Z-axis is taken parallel to the optical axis of an illumination system that applies ultraviolet light to the curable composition on the substrate, and the X-axis and the Y-axis intersecting at right angles are taken in a plane perpendicular to the Z-axis. The planarizing apparatus 1 includes an application station 101, which is a processing area including a first supply unit, a planarization station 102 including a processing area including a second supply unit and separated from the application station 101, and an inter-station conveying mechanism 103.

The application station 101 includes a substrate stage 4, an application unit 5, and a first supply mechanism 6.

The substrate stage 4 is a holding unit including a substrate chuck 11 that holds the substrate 10 by vacuum attraction, for example, and that is movable in an X-Y plane. The substrate 10 is a workpiece made of, for example, monocrystal silicon, on which a curable composition 12 to be molded by the super straight 8 is applied.

The application unit 5 applies the curable composition 12 (uncured curable composition) onto the substrate 10. The curable composition 12 is a photocurable composition having the property of being cured by receiving ultraviolet light and is selected as appropriate in, for example, a semiconductor device manufacturing process.

The first supply mechanism 6 is a supply unit that supplies a first gas for reducing the viscosity of the curable composition 12. The first supply mechanism 6 communicates with the application unit 5, which allows the supplied gas to be mixed with the curable composition 12 in the application unit 5. The first gas supplied from the first supply mechanism 6 dissolves in the curable composition 12 to reduce the viscosity of the curable composition 12, thereby improving the filling performance. The first supply mechanism 6 includes a condensable-gas supply unit 21 that supplies the first gas, which is a condensable gas having the property of being condensed into liquid when pressure is applied (when the pressure is increased).

Usable examples of the condensable gas include HFE and HFC, described above. The first supply mechanism 6 further includes a valve 22 and a gas-supply control unit 23 that controls the amount of gas supplied.

The application unit 5 may be of a cartridge type, in which the condensable gas may be mixed with the curable composition 12 in advance. The use of the condensable-gas supply unit 21 allows correcting a change in the amount of the mixture due to a temperature change.

Mixing the condensable gas in the application unit 5 allows decreasing the viscosity of the high-viscosity curable composition 12, which is difficult to apply by dispensing or which needs an extremely high voltage. This increases options of the curable composition, allowing for selecting a curable composition having high performance required for curable compositions, such as the percentage of contraction and resistance to dry etching.

The planarization station 102 includes an illumination system 2, a mold holding unit 3, a substrate stage 4, and a second supply mechanism 7.

The illumination system 2 is an illumination unit that applies ultraviolet light to a super straight 8 at an imprinting process. The illumination system 2 includes a light source and an optical element for adjusting the ultraviolet light emitted from the light source to light suitable for imprinting (not shown). The super straight 8 is a mold having a very flat surface facing a substrate 10 with irregularities. The super straight 8 is made of a material that allows ultraviolet light to pass through, such as quartz.

The mold holding unit 3 is a holding unit that attracts the super straight 8 using a vacuum attracting force or an electrostatic force. The mold holding unit 3 includes a super straight chuck 9 and a mold driving mechanism (not shown) that drives the mold holding unit 3 in the direction of Z-axis to press the super straight 8 against the ultraviolet curable composition applied on the substrate 10. Mold pressing and releasing operations of the planarizing apparatus 1 may be performed by moving the super straight 8 in the Z direction or may be performed by moving the substrate stage 4 (the substrate 10) in the Z direction or both of the super straight 8 and the substrate stage 4.

The substrate stage 4 is a holding unit including a substrate chuck 11 that holds the substrate 10 by vacuum attraction, for example, and that is movable in an X-Y plane. The substrate 10 is a workpiece made of, for example, monocrystal silicon, on which a curable composition 12 to be molded by the super straight 8 is applied.

The second supply mechanism 7 is a supply unit that supplies a second gas toward a pressing position at which the super straight 8 and the curable composition 12 on the substrate 10 are pressed to each other during the period after the curable composition 12 is applied to the substrate 10 until the pressing. The second supply mechanism 7 may include a permeable-gas supply unit 31 that supplies the second gas, which is a permeable gas having the property of melting or diffusing, to at least one of the super straight 8 and the substrate 10. Employable examples of the permeable gas include helium and hydrogen gases. However, if flammable hydrogen is used as the permeable gas, the imprinting apparatus 1 needs to house an explosion-proof system for protection against fire. The second gas may have low solubility in the curable composition or a low volume ratio even if it is dissolved so as to prevent affecting the contraction of the curable composition pattern when the second gas is released from the cured curable composition pattern. The second gas supplied from the second supply mechanism 6 may be air, nitrogen, or another inert gas. The second supply mechanism 7 further includes a valve 32, a gas-supply control unit 33 that controls the amount of gas supplied, and a gas supply nozzle 34. The use of the second supply mechanism 7 allows the first gas dissolved in the curable composition 12 to be released from the curable composition 12. To release the first gas from the curable composition 12, a decompressing mechanism for decompressing the space between the curable composition on the substrate and the super straight may be provided. A heating mechanism for heating the curable composition on the substrate may be provided.

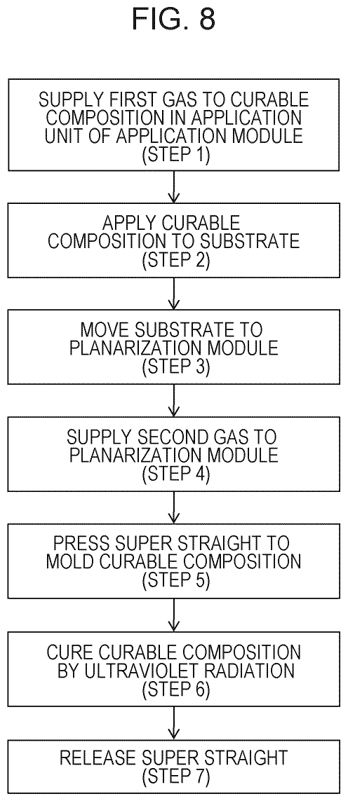

Next, a planarization process performed by the planarizing apparatus 1 will be described. FIG. 8 is a flowchart for the method of planarization according to this embodiment.

First, the first gas is supplied from the first supply mechanism 6 to the curable composition 12 in the application unit 5 of the application station 101 in FIG. 7 (Step 1). The first gas dissolves in the curable composition 12 in the application unit 5 to decrease the viscosity.

Next, the substrate 10 with irregularities is placed and fixed on the substrate stage 4 of the application station 101 by a substrate conveying apparatus (not shown) and thereafter, the substrate stage 4 is moved to an application position of the curable-composition application unit 5. Thereafter, the curable composition 12 is applied from the curable-composition application unit 5 onto the substrate 10 (Step 2). The amount of the curable composition 12 to be ejected from the curable-composition application unit 5 to individual portions of the substrate 10 is adjusted according to the layout of the irregularities of the substrate 10. The curable composition 12 ejected to the substrate 10 spreads over the substrate 10. The viscosity of the curable composition 12 is decreased by the first gas dissolved in the curable-composition application unit 5, which enhances the spread over the substrate 10, preventing non-filling defects.

Next, the substrate 10 of the application station 101 is moved to the planarization station 102 by the inter-station conveying mechanism 103 (Step 3). In the planarization station 102, the substrate stage 4 of the planarization station 102 is moved to a position under the mold holding unit 3 by a substrate conveying apparatus (not shown).

Thereafter, the second gas is supplied from the second supply mechanism 7 to a space between the curable composition 12 on the substrate 10 and the super straight 8 of the planarization station 102 (Step 4). The supply of the second gas causes the first gas dissolved in the curable composition 12 to be released from the curable composition 12. The first gas has high solubility in the curable composition 12. For this reason, if the curable composition 12 in which the first gas is dissolved is cured, the curable composition pattern is contracted to decrease in flatness because the first gas is released from the cured curable composition pattern after the super straight 8 is separated (Step 7, described later). For this reason, the first gas may be released from the curable composition 12 while a space to which the first gas is released remains before the curable composition 12 is cured. The release of the first gas may be accelerated by decreasing the pressure in the space between the curable composition 12 on the substrate 10 and the super straight 8. The release of the first gas may be accelerated by heating the curable composition 12 on the substrate 10.

Next, the curable composition 12 is molded by pressing the super straight 8 to the curable composition 12 on the substrate 10 of the planarization station 102 with a super-straight driving mechanism (not shown) (Step 5). In this state, the illumination system 2 applies ultraviolet light from the top (back) of the super straight 8 to cure the curable composition 12 with the ultraviolet light that has passed through the super straight 8 (Step 6). After the curable composition 12 is cured, the super-straight driving mechanism is activated again to release the super straight 8 from the substrate 10 (Step 7). At that time, the first gas is not released from the curable composition 12, so that the curable composition pattern is not contracted, allowing keeping the flatness.

Thus, this embodiment includes the application station 101 and the planarization station 102. This configuration allows rapid gas exchange, providing a planarizing apparatus and a method of planarization that are advantageous in satisfying both of filling performance and flatness.

### Fourth Embodiment

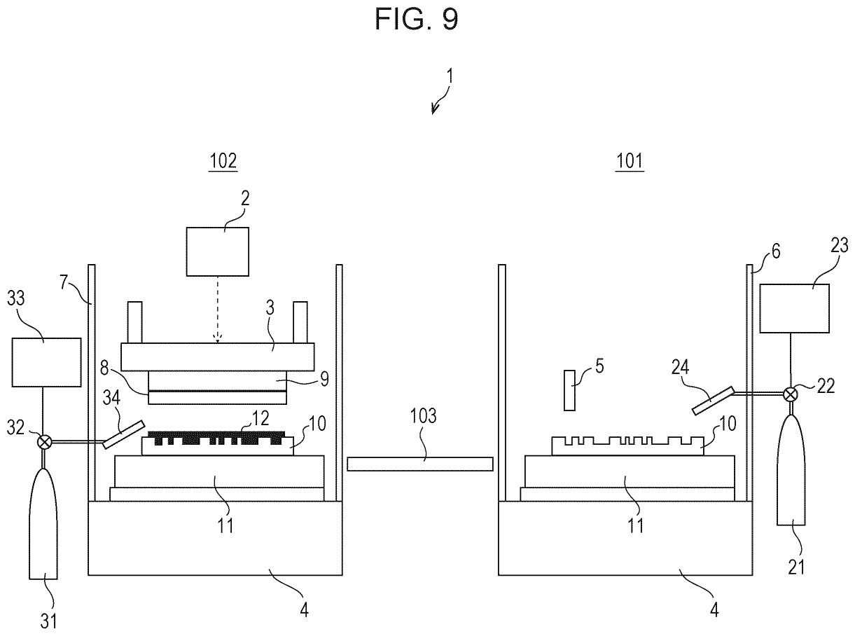

A planarizing apparatus according to a fourth embodiment will be described with reference to FIG. 9. FIG. 9 is a diagram illustrating the planarizing apparatus of the fourth embodiment. The planarizing apparatus is used to produce devices, such as semiconductor devices, and molds a curable composition (typically, an uncured curable composition) on a substrate, which is a workpiece, with a mold having a flat surface (a super straight) to mold a flat surface pattern (typically, a curable composition pattern) on the substrate. Here, the planarizing apparatus employs a photo-curing method. In the following diagrams, the Z-axis is taken parallel to the optical axis of an illumination system that applies ultraviolet light to the curable composition on the substrate, and the X-axis and the Y-axis intersecting at right angles are taken in a plane perpendicular to the Z-axis. The planarizing apparatus 1 includes an application station 101, a planarization station 102, and an inter-station conveying mechanism 103.

The application station 101 includes a substrate stage 4, an application unit 5, and a first supply mechanism 6.

The substrate stage 4 is a holding unit including a substrate chuck 11 that holds the substrate 10 by vacuum attraction, for example, and that is movable in an X-Y plane. The substrate 10 is a workpiece made of, for example, monocrystal silicon, on which a curable composition 12 to be molded by the super straight 8 is applied.

The application unit 5 applies the curable composition 12 (uncured curable composition) onto the substrate 10. The curable composition 12 is a photocurable composition having the property of being cured by receiving ultraviolet light and is selected as appropriate in, for example, a semiconductor device manufacturing process.

The first supply mechanism 6 is a supply unit that supplies a first gas for reducing the viscosity of the curable composition 12. The first supply mechanism 6 supplies the first gas toward the substrate 10 in an application process in which the curable composition 12 is applied onto the substrate 10. The first gas supplied from the first supply mechanism 6 dissolves in the curable composition 12 to reduce the viscosity of the curable composition 12, thereby improving the filling performance. The first supply mechanism 6 includes a condensable-gas supply unit 21 that supplies the first gas, which is a condensable gas having the property of being condensed into liquid when pressure is applied (when the pressure is increased).

Examples of the condensable gas include HFE and HFC, described above. The first supply mechanism 6 further includes a valve 22, a gas-supply control unit 23 that controls the amount of gas supplied, and a gas supply nozzle 24.

The planarization station 102 includes an illumination system 2, a mold holding unit 3, a substrate stage 4, and a second supply mechanism 7.

The illumination system 2 is an illumination unit that applies ultraviolet light to a super straight 8 at an imprinting process. The illumination system 2 includes a light source and an optical element for adjusting the ultraviolet light emitted from the light source to light suitable for imprinting (not shown). The super straight 8 is a mold having a very flat surface facing a substrate 10 with irregularities. The super straight 8 is made of a material that allows ultraviolet light to pass through, such as quartz.

The mold holding unit 3 is a holding unit that attracts the super straight 8 using a vacuum attracting force or an electrostatic force. The mold holding unit 3 includes a super straight chuck 9 and a mold driving mechanism (not shown) that drives the mold holding unit 3 in the direction of Z-axis to press the super straight 8 against the ultraviolet curable composition applied on the substrate 10. Mold pressing and releasing operations of the planarizing apparatus 1 may be performed by moving the super straight 8 in the Z direction or may be performed by moving the substrate stage 4 (the substrate 10) in the Z direction or both of the super straight 8 and the substrate stage 4.

The substrate stage 4 is a holding unit including a substrate chuck 11 that holds the substrate 10 by vacuum attraction, for example, and that is movable in an X-Y plane. The substrate 10 is a workpiece made of, for example, monocrystal silicon, on which a curable composition 12 to be molded by the super straight 8 is applied.

The second supply mechanism 7 is a supply unit that supplies a second gas toward a pressing position at which the super straight 8 and the curable composition 12 on the substrate 10 are pressed to each other during the period after the curable composition 12 is applied to the substrate 10 until the pressing. The second supply mechanism 7 may include a permeable-gas supply unit 31 that supplies the second gas, which is a permeable gas having the property of melting or diffusing, to at least one of the super straight 8 and the substrate 10. Employable examples of the permeable gas include helium and hydrogen gases. However, if flammable hydrogen is used as the permeable gas, the imprinting apparatus 1 needs to house an explosion-proof system for protection against fire. The second gas may have low solubility in the curable composition or a low volume ratio even if dissolved to prevent affecting the contraction of the curable composition pattern when the second gas is released from the cured curable composition pattern. The second gas supplied from the second supply mechanism 6 may be air, nitrogen, or another inert gas. The second supply mechanism 7 further includes a valve 32, a gas-supply control unit 33 that controls the amount of gas supplied, and a gas supply nozzle 34. The use of the second supply mechanism 7 allows the first gas dissolved in the curable composition 12 to be released from the curable composition 12. To release the first gas from the curable composition 12, a mechanism for decompressing the space between the curable composition on the substrate and the super straight may be provided. A heating mechanism for heating the curable composition on the substrate may be provided.

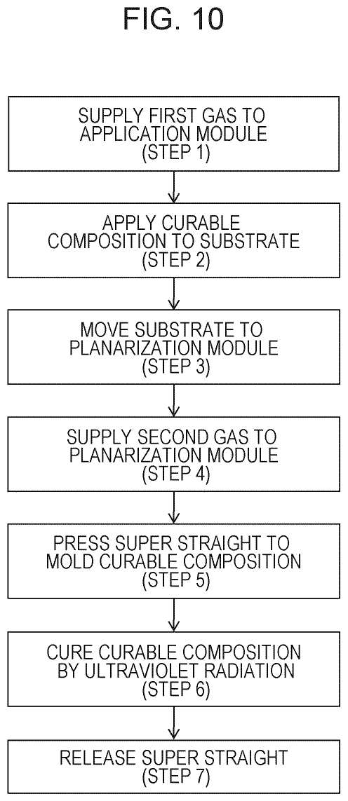

Next, a planarization process performed by the planarizing apparatus 1 will be described. FIG. 10 is a flowchart for the method of planarization according to this embodiment.

First, the substrate 10 with irregularities is placed and fixed on the substrate stage 4 by a substrate conveying apparatus (not shown) in the application station 101 of FIG. 9, and thereafter, the substrate stage 4 is moved to an application position of the curable-composition application unit 5. Thereafter, the first gas is supplied from the first supply mechanism 6 into the space on the substrate 10 (Step 1).

Next, the curable composition 12 is applied from the application unit 5 of the application station 101 onto the substrate 10 (Step 2). The amount of the curable composition 12 to be ejected from the curable-composition application unit 5 to individual portions of the substrate 10 is adjusted according to the layout of the irregularities of the substrate 10. The viscosity of the curable composition 12 is decreased by the first gas dissolved in the curable-composition application unit 5. The decrease in the viscosity enhances the spread of the curable composition 12 over the substrate 10, preventing non-filling defects.

Next, the substrate 10 of the application station 101 is moved to the planarization station 102 by the inter-station conveying mechanism 103 (Step 3). In the planarization station 102, the substrate stage 4 of the planarization station 102 is moved to a position under the mold holding unit 3 by a substrate conveying apparatus (not shown).

Thereafter, the second gas is supplied from the second supply mechanism 7 to a space between the curable composition 12 on the substrate 10 and the super straight 8 of the planarization station 102 (Step 4). The supply of the second gas causes the first gas dissolved in the curable composition 12 to be released from the curable composition 12. The first gas has high solubility in the curable composition 12. For this reason, if the curable composition 12 in which the first gas is dissolved is cured, the curable composition pattern is contracted to decrease in flatness because the first gas is released from the cured curable composition pattern after the super straight 8 is separated (Step 7, described later). For this reason, the first gas may be released from the curable composition 12 while a space to which the first gas is released remains before the curable composition 12 is cured. The release of the first gas may be accelerated by decreasing the pressure in the space between the curable composition 12 on the substrate 10 and the super straight 8. The release of the first gas may be accelerated by heating the curable composition 12 on the substrate 10.

Next, the curable composition 12 is molded by pressing the super straight 8 to the curable composition 12 on the substrate 10 of the planarization station 102 with a super-straight driving mechanism (not shown) (Step 5). In this state, the illumination system 2 applies ultraviolet light from the top (back) of the super straight 8 to cure the curable composition 12 with the ultraviolet light that has passed through the super straight 8 (Step 6). After the curable composition 12 is cured, the super-straight driving mechanism is activated again to release the super straight 8 from the substrate 10 (Step 7). At that time, the first gas is not released from the curable composition 12, so that the curable composition pattern is not contracted because of the released first gas, allowing keeping the flatness.

Thus, this embodiment includes the application station 101 and the planarization station 102. This configuration allows rapid gas exchange, providing a planarizing apparatus and a method of planarization that are advantageous in satisfying both of filling performance and flatness.

### Fifth Embodiment

A planarizing apparatus according to a fifth embodiment will be described with reference to FIG. 9. The planarizing apparatus is used to produce devices, such as semiconductor devices, and molds a curable composition (typically, an uncured curable composition) on a substrate, which is a workpiece, with a mold having a flat surface (a super straight) to mold a flat surface pattern (typically, a curable composition pattern) on the substrate. Here, the planarizing apparatus employs a photo-curing method. In the following diagrams, the Z-axis is taken parallel to the optical axis of an illumination system that applies ultraviolet light to the curable composition on the substrate, and the X-axis and the Y-axis intersecting at right angles are taken in a plane perpendicular to the Z-axis. The planarizing apparatus 1 includes an application station 101, a planarization station 102, and an inter-station conveying mechanism 103.

The application station 101 includes a substrate stage 4, an application unit 5, and a first supply mechanism 6.

The substrate stage 4 is a holding unit including a substrate chuck 11 that holds the substrate 10 by vacuum attraction, for example, and that is movable in an X-Y plane. The substrate 10 is a workpiece made of, for example, monocrystal silicon, on which a curable composition 12 to be molded by the super straight 8 is applied.

The application unit 5 applies the curable composition 12 (uncured curable composition) onto the substrate 10. The curable composition 12 is a photocurable composition having the property of being cured by receiving ultraviolet light and is selected as appropriate in, for example, a semiconductor device manufacturing process.

The first supply mechanism 6 supplies the first gas toward the substrate 10 in an application process in which the curable composition 12 is applied onto the substrate 10. The first gas supplied from the first supply mechanism 6 may be clean dry air or inert gas, such as nitrogen. The first supply mechanism 6 includes a valve 22, a gas-supply control unit 23 that controls the amount of gas supplied, and a gas supply nozzle 24.

The planarization station 102 includes an illumination system 2, a mold holding unit 3, a substrate stage 4, and a second supply mechanism 7.

The illumination system 2 is an illumination unit that applies ultraviolet light to a super straight 8 at an imprinting process. The illumination system 2 includes a light source and an optical element for adjusting the ultraviolet light emitted from the light source to light suitable for imprinting (not shown). The super straight 8 is a mold having a very flat surface facing a substrate 10 with irregularities. The super straight 8 is made of a material that allows ultraviolet light to pass through, such as quartz.

The mold holding unit 3 is a holding unit that attracts the super straight 8 using a vacuum attracting force or an electrostatic force. The mold holding unit 3 includes a super straight chuck 9 and a mold driving mechanism (not shown) that drives the mold holding unit 3 in the direction of Z-axis to press the super straight 8 against the ultraviolet curable composition applied on the substrate 10. Mold pressing and releasing operations of the planarizing apparatus 1 may be performed by moving the super straight 8 in the Z direction or may be performed by moving the substrate stage 4 (the substrate 10) in the Z direction or both of the super straight 8 and the substrate stage 4.

The substrate stage 4 is a holding unit including a substrate chuck 11 that holds the substrate 10 by vacuum attraction, for example, and that is movable in an X-Y plane. The substrate 10 is a workpiece made of, for example, monocrystal silicon, on which a curable composition 12 to be molded by the super straight 8 is applied.

The second supply mechanism 7 is a supply unit that supplies a second gas toward a pressing position at which the super straight 8 and the curable composition 12 on the substrate 10 are pressed to each other during the period after the curable composition 12 is applied to the substrate 10 until the pressing. The second supply mechanism 7 may include a permeable-gas supply unit 31 that supplies the second gas, which is a permeable gas having the property of melting or diffusing, to at least one of the super straight 8 and the substrate 10. Employable examples of the permeable gas include helium and hydrogen gases. However, if flammable hydrogen is used as the permeable gas, the imprinting apparatus 1 needs to house an explosion-proof system for protection against fire.

Next, a planarization process performed by the planarizing apparatus 1 will be described. FIG. 10 is a flowchart for the method of planarization according to this embodiment.

First, the substrate 10 with irregularities is placed and fixed on the substrate stage 4 by a substrate conveying apparatus (not shown) in the application station 101 of FIG. 9, and thereafter, the substrate stage 4 is moved to an application position of the curable-composition application unit 5. Thereafter, the first gas is supplied from the first supply mechanism 6 into the space on the substrate 10 (Step 1).

Next, the curable composition 12 is applied from the application unit 5 of the application station 101 onto the substrate 10 (Step 2). The amount of the curable composition 12 to be ejected from the curable-composition application unit 5 to individual portions of the substrate 10 is adjusted according to the layout of the irregularities of the substrate 10. Using clean dry air or nitrogen as the first gas reduces the amount of helium or hydrogen used as the second gas,

Next, the substrate 10 of the application station 101 is moved to the planarization station 102 by the inter-station conveying mechanism 103 (Step 3). In the planarization station 102, the substrate stage 4 of the planarization station 102 is moved to a position under the mold holding unit 3 by a substrate conveying apparatus (not shown).

Thereafter, the second gas is supplied from the second supply mechanism 7 to a space between the curable composition 12 on the substrate 10 and the super straight 8 of the planarization station 102 (Step 4).

Next, the curable composition 12 is molded by pressing the super straight 8 to the curable composition 12 on the substrate 10 of the planarization station 102 with a super-straight driving mechanism (not shown) (Step 5). In this state, the illumination system 2 applies ultraviolet light from the top (back) of the super straight 8 to cure the curable composition 12 with the ultraviolet light that has passed through the super straight 8 (Step 6). After the curable composition 12 is cured, the super-straight driving mechanism is activated again to release the super straight 8 from the substrate 10 (Step 7).

Thus, this embodiment includes the application station 101 and the planarization station 102. This configuration allows rapid gas exchange, providing a planarizing apparatus and a method of planarization that increase the productivity.

### Sixth Embodiment

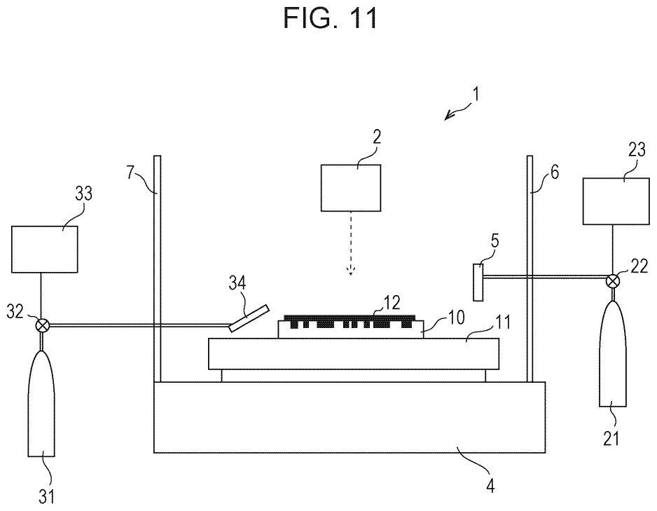

A planarizing apparatus according to a sixth embodiment will be described with reference to FIG. 11. FIG. 11 is a diagram illustrating the planarizing apparatus according to the sixth embodiment. The planarizing apparatus is used to produce devices, such as semiconductor devices, and molds a curable composition (typically, an uncured curable composition) on a substrate, which is a workpiece, without using a flat mold to mold a flat surface pattern (typically, a curable composition pattern) on the substrate. Here, the planarizing apparatus employs a photo-curing method. In the following diagrams, the Z-axis is taken parallel to the optical axis of an illumination system that applies ultraviolet light to the curable composition on the substrate, and the X-axis and the Y-axis intersecting at right angles are taken in a plane perpendicular to the Z-axis. The planarizing apparatus 1 includes an illumination system 2, a substrate stage 4, an application unit 5, a first supply mechanism 6, and a second supply mechanism 7. Since this planarizing apparatus 1 performs molding without using a flat mold, the planarizing apparatus 1 does not include the mold holding unit 3 and the super straight 8, which are provided for the planarizing apparatus 1 of the first embodiment in FIG. 1.

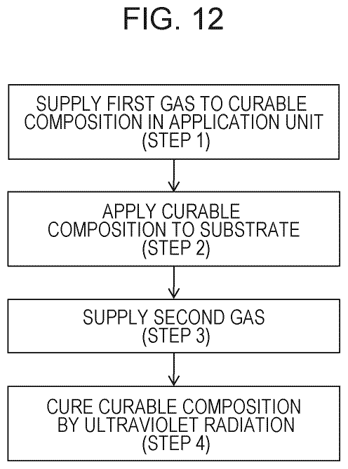

Next, a planarization process performed by the planarizing apparatus 1 will be described. FIG. 12 is a flowchart for the method of planarization according to this embodiment.

First, the first gas is supplied from the first supply mechanism 6 to the curable composition 12 in the application unit 5 of FIG. 11 (Step 1). The first gas dissolves in the curable composition 12 in the application unit 5 to decrease the viscosity.

Next, the substrate 10 with irregularities is placed and fixed on the substrate stage 4 by a substrate conveying apparatus (not shown), and thereafter the substrate stage 4 is moved to an application position of the curable-composition application unit 5. Thereafter, the curable composition 12 is applied from the curable composition-application unit 5 onto the substrate 10 (Step 2). The amount of the curable composition 12 to be ejected from the curable-composition application unit 5 to individual portions of the substrate 10 is adjusted according to the layout of the irregularities of the substrate 10. The curable composition 12 ejected to the substrate 10 spreads over the substrate 10. The viscosity of the curable composition 12 is decreased by the first gas dissolved in the curable-composition application unit 5, which enhances the spread over the substrate 10, preventing non-filling defects.

Next, the second gas is supplied from the second supply mechanism 7 to the space on the curable composition 12 on the substrate 10 (Step 3). The supply of the second gas causes the first gas dissolved in the curable composition 12 to be released from the curable composition 12. The first gas has high solubility in the curable composition 12. For this reason, if the curable composition 12 in which the first gas is dissolved is cured, the curable composition pattern is contracted to decrease in flatness because of the first gas released from the cured curable composition pattern. For this reason, the first gas may be released from the curable composition 12 before the curable composition 12 is cured.

Next, the illumination system 2 applies ultraviolet light to cure the curable composition 12 (Step 4). At that time, the first gas is not released from the curable composition 12, so that the curable composition pattern is not contracted by the released first gas, keeping the flatness.

Thus, this embodiment provides a planarizing apparatus and a method of planarization that are advantageous in satisfying both of filling performance and flatness.

### Seventh Embodiment

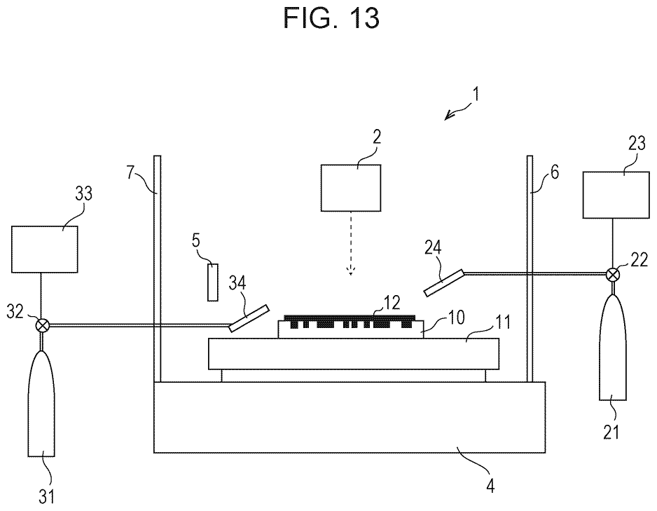

A planarizing apparatus according to a seventh embodiment will be described with reference to FIG. 13. FIG. 13 is a diagram illustrating the planarizing apparatus according to the seventh embodiment. The planarizing apparatus is used to produce devices, such as semiconductor devices, and molds a curable composition (typically, an uncured curable composition) on a substrate, which is a workpiece, without using a flat mold to mold a flat surface pattern (typically, a curable composition pattern) on the substrate. Here, the planarizing apparatus employs a photo-curing method. In the following diagrams, the Z-axis is taken parallel to the optical axis of an illumination system that applies ultraviolet light to the curable composition on the substrate, and the X-axis and the Y-axis intersecting at right angles are taken in a plane perpendicular to the Z-axis. The planarizing apparatus 1 includes an illumination system 2, a substrate stage 4, an application unit 5, a first supply mechanism 6, and a second supply mechanism 7. Since this planarizing apparatus 1 performs molding without using a flat mold, the planarizing apparatus 1 does not include the mold holding unit 3 and the super straight 8, which are provided for the planarizing apparatus 1 of the second embodiment in FIG. 5.

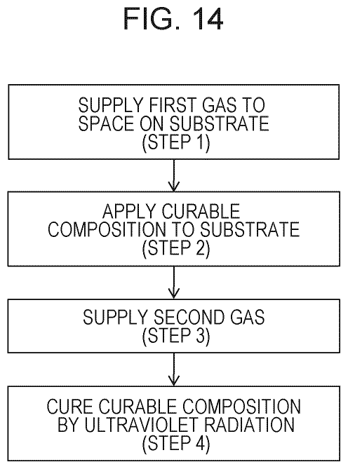

Next, a planarization process performed by the planarizing apparatus 1 will be described. FIG. 14 is a flowchart for the method of planarization according to this embodiment.

First, the substrate 10 with irregularities is placed and fixed on the substrate stage 4 by a substrate conveying apparatus (not shown in FIG. 13), and thereafter, the substrate stage 4 is moved to an application position of the curable-composition application unit 5. Thereafter, the first gas is supplied from the first supply mechanism 6 into the space on the substrate 10 (Step 1).

Next, the curable composition 12 is applied from the curable-composition application unit 5 onto the substrate 10 (Step 2). The amount of the curable composition 12 to be ejected from the curable-composition application unit 5 to individual portions of the substrate 10 is adjusted according to the layout of the irregularities of the substrate 10. The viscosity of the curable composition 12 is decreased by the first gas dissolved in the curable-composition application unit 5. The decrease in the viscosity enhances the spread of the curable composition 12 over the substrate 10, and providing a predetermined waiting time flattens the surface of the curable composition 12, preventing non-filling defects.

Next, the second gas is supplied from the second supply mechanism 7 to the space on the curable composition 12 on the substrate 10 (Step 3). The supply of the second gas causes the first gas dissolved in the curable composition 12 to be released from the curable composition 12. The first gas has high solubility in the curable composition 12. For this reason, if the curable composition 12 in which the first gas is dissolved is cured, the curable composition pattern is contracted to decrease in flatness because of the first gas released from the cured curable composition pattern. For this reason, the first gas may be released from the curable composition 12 before the curable composition 12 is cured.

Next, the illumination system 2 applies ultraviolet light to cure the curable composition 12 (Step 4). At that time, the first gas is not released from the curable composition 12, so that the curable composition pattern is not contracted by the released first gas, keeping the flatness.

Thus, this embodiment provides a planarizing apparatus and a method of planarization that are advantageous in satisfying both of filling performance and flatness.

While the present disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

What is claimed is:

1. A method of molding, comprising:
applying a curable composition on a substrate;
supplying a first gas that decreases viscosity of the curable composition to the curable composition;
forming a film of the curable composition incorporating the first gas on the substrate;
supplying a second gas to the film on the substrate, the second gas accelerates release of the first gas from the curable composition; and
after supplying the second gas, illuminating to cure the film of the curable composition on the substrate.

2. The method of molding according to claim 1, wherein after the supplying of the first gas to the curable composition, the applying of the curable composition incorporating the first gas onto the substrate is performed.

3. A method of planarization using the method of molding according to claim 1, the method comprising:
illuminating to cure the film of the curable composition to form a flat surface.

4. The method of planarization according to claim 3, the method further comprising:
bringing a mold having a flat surface into contact with the curable composition to form the film having a flat surface.

5. The method of planarization according to claim 3, further comprising:
waiting until the flat surface is formed without bringing the mold into contact with the curable composition on the substrate.

6. A method for producing an object, the method comprising:
applying a curable composition onto a substrate using the substrate using the method of molding according to claim 1; and
pressing a mold having a flat surface into contact with the curable composition on the substrate.
